(19) United States
(12) Patent Application Publication
(10) Pub. No.: US 2008/0315689 A1
(43) Pub. Date: Dec. 25, 2008

(54) ULTRA SHORT HIGH VOLTAGE PULSE GENERATOR BASED ON SINGLE OR DOUBLE SPARK GAP

(76) Inventor: Dmirty Medvedev, Moscow (RU)

Correspondence Address: PORTER WRIGHT MORRIS & ARTHUR, LLP;INTELLECTUAL PROPERTY GROUP, 41 SOUTH HIGH STREET, 28TH FLOOR, COLUMBUS, OH, 43215, US

(21) Appl. No.: 12/139,566

(22) Filed: Jun. 16, 2008

Related U.S. Application Data
(60) Provisional application No. 60/944,265, filed on Jun. 15, 2007.

(51) Int. Cl. H03K 3/00

(52) U.S. Cl. 307/108

(57) ABSTRACT

A method and system for the generation of high voltage, pulsed, periodic dielectric barrier or corona discharges is capable of being used in the presence of conductive liquid droplets and over contaminated or uneven surfaces. The method and system can be used, for example, in different devices for cleaning of gaseous or liquid media or for surface sterilization using pulsed dielectric barrier or corona discharge. The pulsed power generator includes a storage capacitor a high voltage switch operably connected to said storage capacitor, and a charger of the storage capacitor which generates charging pulses until a spark gap breakdown occurs which gives a feedback signal to stop further charging until the beginning of the next charging cycle.

### CROSS-REFERENCE TO RELATED APPLICATIONS

This application claims the priority benefit of U.S. Provisional Patent Application No. 60/944,265 filed on Jun. 15, 2007, the disclosure of which is expressly incorporated herein in its entirety by reference.

### STATEMENT REGARDING FEDERALLY SPONSORED RESEARCH

Not Applicable

### REFERENCE TO MICROFICHE APPENDIX

Not Applicable

### BACKGROUND OF THE INVENTION

1. Field of the Invention

The field of the present invention relates to the generation of electrical discharges for plasma catalysis, environmental control technology, sterilization, disinfection, medical and other applications. In more particular the invention relates to a method and system for the generation of high voltage, pulsed, periodic dielectric barrier discharge or other pulse discharges, i.e. ionization wave and pulsed corona discharge.

2. Description of Related technology

Systems based on pulsed high voltage, applied for example for generation of dielectric barrier discharge, pulsed corona discharges, or ionization wave discharges, are among the most promising approaches in the fields of plasma catalysis, environmental control technology, sterilization, disinfection, medical and other plasma discharge applications. Such systems are used for ignition and combustion control, sterilization, disinfection, and cleaning of water, air, surfaces, fuel and vent gases, and for treatment and activation of various surfaces. Further development of these systems is limited by the lack of cost-effective and reliable power supplies that can generate short high voltage pulses and that have necessary characteristics for industrial and medical applications. Methods of matching these power supplies with non-linear load, for example dielectric barrier discharge or pulsed corona discharge, are also lacking. This matching is desirable in order to achieve reasonable energy input efficiency into the load.

Today most of the methods for generation of short high voltage pulses are based on the use of thyratrons, which are gas-filled hot-cathode electron tubes in which the grid controls only the start of a continuous current thus giving the tubes a trigger effect, or triggered spark gaps (with a third electrode or rotating electrodes). These methods have the following drawbacks. Industrial thyratrons, as well as triggered spark gaps, are relatively expensive and have a short life time as generators of short pulses. Moreover, use of thyratrons or triggered spark gaps demands additional power for thyratron cathode heating, or for the formation of control pulses (triggering) or the rotation of electrodes. This reduces the overall energy efficiency of the pulse generator. Also, thyratrons require time post-pulse to cool down and thus the maximum frequency of pulses achievable in these systems is limited.

The use of untriggered spark gaps that have the best time characteristics when generating single pulses in conventional methods with ballast (serial) resistors results in very large energy losses during charging of the discharge capacitor (ohmic heating loss can be more than 50%). Furthermore, the typical untriggered spark gap cannot provide the high frequencies of pulse generation (1000 Hz and higher) that are necessary for commercial applications of the pulsed dielectric barrier discharges such as gas cleaning, or surface sterilization.

Russian Patent No. 2,144,257, the disclosure of which is expressly incorporated herein in its entirety by reference, discloses a device that was developed for generation of short pulses of high voltage for ignition of pulsed-periodic electric discharges like pulsed corona discharges or pulsed dielectric barrier discharges. The device can generate high voltage pulses with extremely short rise times (up to 5-10 ns) with high pulse repetition frequencies (about 2000 Hz) and with a maximal energy efficiency of the device (COP) on the level of 90%. The device comprises a high voltage power supply, a discharge capacitor, and a high voltage commutation switch that connects a discharge capacitor and a load. The high voltage power supply comprises a main rectifier, a semiconductor converter, and one or more pulsed high voltage transformers that provide charging of the discharge capacitor by small portions that form in each operation of the converter, so that the frequency of charging pulses of the discharge capacitor is at least three times larger than the frequency of the high voltage communication switch operation. The high voltage communication switch is made as an untriggered spark gap in which one or both electrodes are made in the form of one or several pins, threads, needles, blades or other components with sharp edges, so that corona discharge appears on these edges when the voltage between the gap electrodes is still below the breakdown voltage.

The method used in the above device has an important drawback: the residual high voltage exists on the electrodes of, for example, a pulsed corona chamber between corona pulses. This voltage corresponds to an extinguishing voltage of the pulsed corona discharge. Because of this drawback, this device cannot be used for the generation of corona discharge in the presence of droplets of water (e.g. spray, fog) or other conductive liquids in the discharge chamber; or for generation of short-pulsed dielectric barrier discharges between one or two dielectrics, or between a dielectric-covered electrode and the surface designated for plasma treatment, cleaning, and/or sterilization.

Additionally this device cannot be used for generation of uniform dielectric barrier discharge over uneven and/or contaminated surfaces. These options are extremely important for many commercial applications of the pulsed dielectric barrier discharge for water, or surface cleaning, disinfection, or sterilization to enable hetero-phase plasma chemical reactions.

U.S. Provisional Patent Application No. 60/807,472 (DREX-1027USP), the disclosure of which is expressly incorporated herein in its entirety by reference, discloses a method and system for the generation of high voltage, pulsed, periodic corona discharges capable of being used in the presence of conductive liquid droplets. This system is analogues to the system described above but electrodes of pulse corona discharge are short cut by an inductor. This solution, and a special shape of the corona electrodes, solves the problem of operation of corona discharge in the presence of liquid conductive droplets because this inductor removes residual electric voltage from the corona electrodes. But such an approach causes additional energy losses during the time of spark (in spark gap) extinguishing because at this time, the high voltage power supply appears to be loaded directly on the inductor and uselessly spends energy. Another disadvantage of this approach is the limitation of operation frequency of the system because the current through the spark gap at the time of spark extinguishing elongates the time.

Accordingly, there exists a need for providing an improved method and system for the generation of high voltage, pulsed, periodic dielectric barrier or corona discharges capable of being used, for example, in the presence of conductive liquid droplets, in varying humidity, and over contaminated and uneven surfaces.

### SUMMARY OF THE INVENTION

The present invention provides a method and system which addresses at least some of the above-noted problems of the related art. Disclosed is a method and system for the generation of high voltage, pulsed, periodic dielectric barrier or corona discharges capable of being used in the presence of conductive liquid droplets, in varying humidity, and over contaminated surfaces.

From the foregoing disclosure and the following more detailed description of various preferred embodiments it will be apparent to those skilled in the art that the present invention provides a significant advance in the technology. Additional features and advantages of various preferred embodiments will be better understood in view of the detailed description provided below.

### BRIEF DESCRIPTION OF THE DRAWINGS

These and further features of the present invention will be apparent with reference to the following description and drawing, wherein:

FIG. 1 is a functional schematic of a generator of variable frequency pulses;

FIG. 2 a temporal diagram of the development and formation of the driving pulses at the points A, B, E, and Q, corresponding to the respective points on FIG. 1. and the resulting voltage;

FIG. 3 is a principal schematic of the high voltage high frequency power supply utilizing modular pulse control;

FIG. 4A is a diagrammatic view of a pulsed discharge generator based on a single spark gap;

FIG. 4B is a diagrammatic view of a pulsed discharge generator based on a double spark gap;

FIG. 5 is a diagrammatic view of a setup for construction of a Dielectric Barrier Discharge (DBD) operating in a nanosecond pulse-width regime and based on a double spark gap;

FIG. 6 is a diagrammatic view of a setup for capturing a single pulse of Dielectric Barrier Discharge plasma on photographic film;

FIG. 7 is a photographic image created by a single pulse of Dielectric Barrier Discharge plasma on a photographic film; and

FIG. 8 is a screen capture of a digital oscilloscope showing the voltage and current profiles of a single pulse of the nanosecond duration Dielectric Barrier Discharge.

It should be understood that the appended drawings are not necessarily to scale, presenting a somewhat simplified representation of various preferred features illustrative of the basic principles of the invention. The specific design features as disclosed herein, including, for example, specific dimensions and shapes of the various components will be determined in part by the particular intended application and use environment. Certain features of the illustrated embodiments have been enlarged or distorted relative to others to facilitate visualization and clear understanding. In particular, thin features may be thickened, for example, for clarity or illustration. All references to direction and position, unless otherwise indicated, refer to the orientation of the system illustrated in the drawings.

### DETAILED DESCRIPTION OF CERTAIN PREFERRED EMBODIMENTS

It will be apparent to those skilled in the art, that is, to those who have knowledge or experience in this area of technology, that many uses and design variations are possible for the improved method and system disclosed herein. The following detailed discussion of various alternative and preferred embodiments will illustrate the general principles of the invention. Other embodiments suitable for other applications will be apparent to those skilled in the art given the benefit of this disclosure.

The instant invention provides a method and system for the generation of high voltage, pulsed, periodic dielectric barrier or corona discharges capable of being used in the presence of conductive liquid droplets, in varying humidity, and over contaminated surfaces. The invention can be used, for example, in different devices for generation of uniform dielectric barrier discharge plasma for treatment and sterilization of various uneven and contaminated surfaces.

One of the main difficulties in the development of high voltage short pulsed power supplies is the matching of energy of pulse generated by power supply with the energy dissipated in the load. The other important problem is switching off of the high voltage switcher after the pulse subsides. The current invention solves both of these problems and provides the possibility to produce a high efficiency generator of extremely short pulses using a reliable and simple pulse switcher like an uncontrolled spark gap.

The result of the method and system is the formation of high voltage pulses with an extremely short rise time, for example, up to 5-20 nanoseconds, and with high pulse repetition frequency, for example, up to 2000 Hz. The high voltage pulses facilitate maximum efficiency plasma chemical oxidation of detrimental impurities, and increase the range of stable discharge operations in the presence of droplets of water or other conductive liquids in the discharge zone.

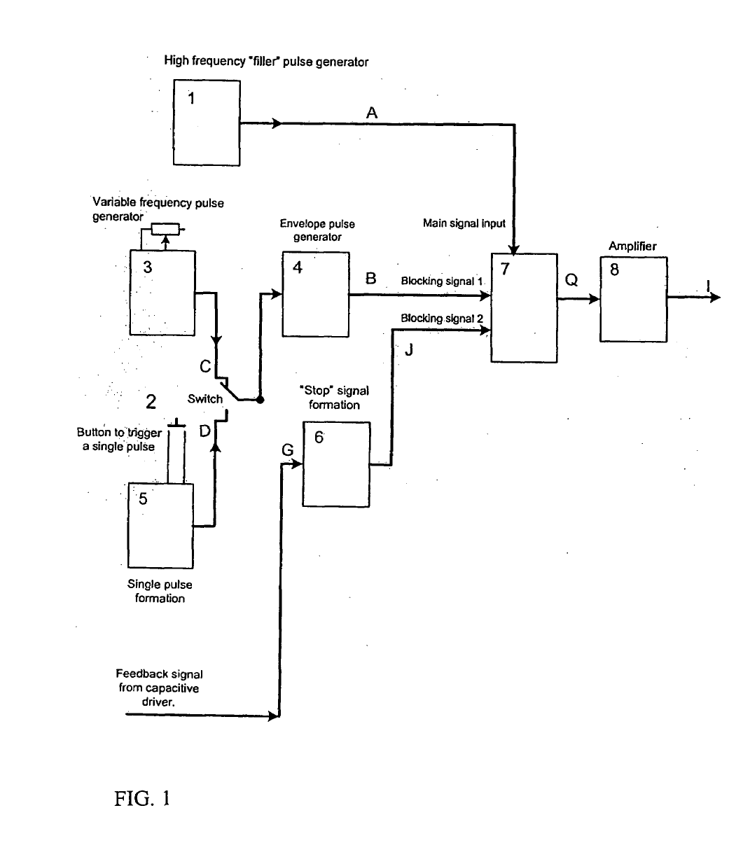

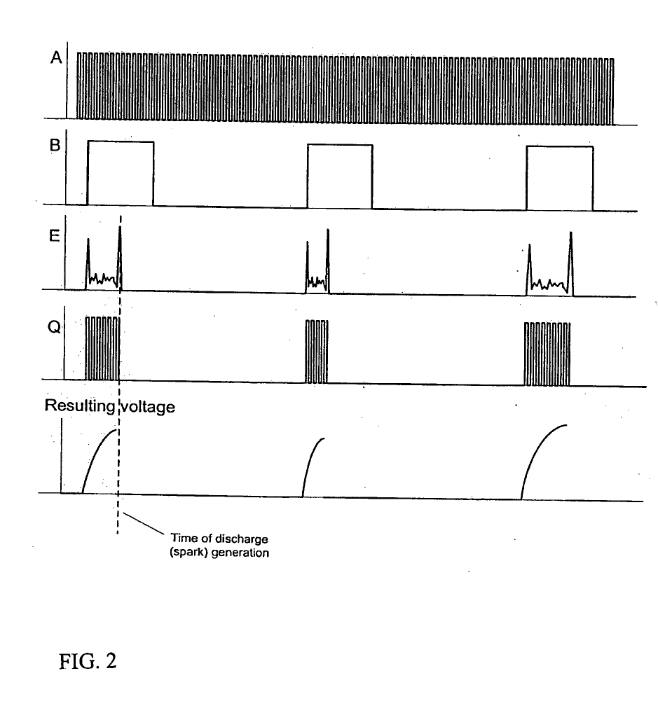

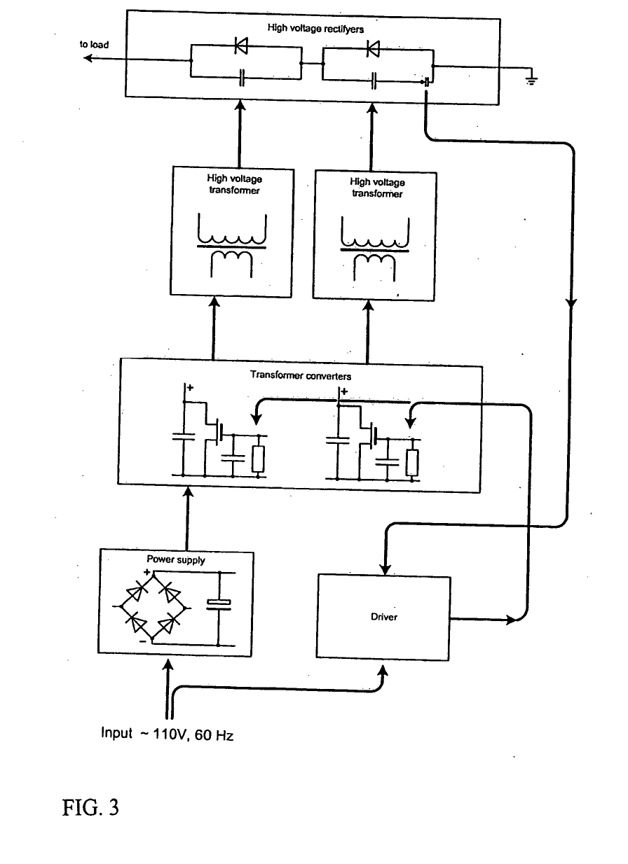

It is possible to achieve this using a device comprising a high voltage power supply principal of operation of which is shown in FIGS. 1 to 3. FIG. 3 shows a principal schematic of the high voltage high frequency power supply unit which utilizes modular pulse control. FIG. 1 shows a functional schematic of the generator of variable frequency pulses which, depending on the input, are able to produce variable duration high voltage pulses shown in FIG. 2. A high frequency “filler” pulse generator (1) is operably connected to a transistor set (7). The high frequency “filler” pulse generator (1) sets the overall driving pulse or signal (A) to a transistor set (7). The main pulse (A) is enveloped by a driving pulse or signal (B) generated by an envelope pulse generator (4) operably connected to the transistor set (7). A variable frequency pulse generator (3) and a single pulse generator (5) are each operably connected to the envelope pulse generator (4). When a variable frequency pulse (C) generated by the variable frequency pulse generator (3) is applied to envelope the “filler” pulses, or when a single pulse (D) generated by the single pulse generator (5) is requested through a push-button or trigger (2), the charging starts. Once the discharge ignites (E) there is a current spike through the circuit as the plasma is discharging which triggers the transistor set (7) to stop charging, thus creating optimal conditions for spark gap distinguishing and removing energy losses while spark gap distinguishing. This is important as the envelope signal (B) defines the maximum pulse duration and if the discharge ignites prior to the closure of the enveloping signal the charging of capacitors terminates thus conserving power and, more importantly, creating optimal conditions for spark gap distinguishing and removing energy losses while spark gap distinguishing. The output signal (Q) from the transistor set (7) is provided to an amplifier (8) which produces an amplified signal (I). A feedback signal (G) from the capacitive driver is provided to a “stop” signal generator (6) which in turn provides a stop signal (J) to the transistor (7). The feedback signal stops further charging until the beginning of the next charging cycle.

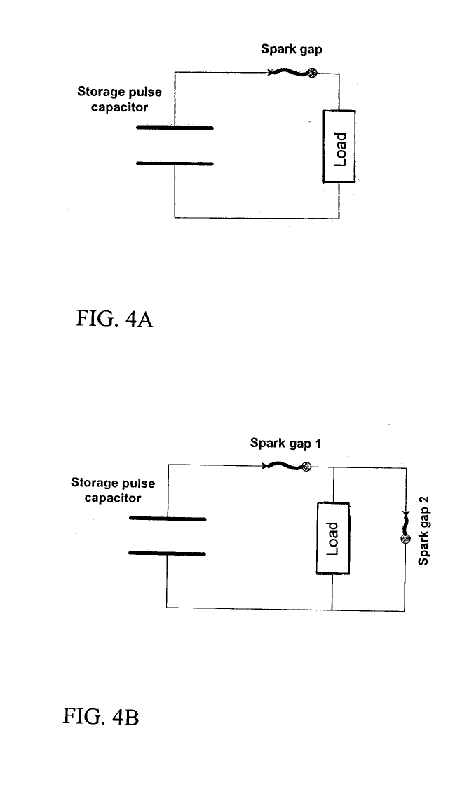

FIGS. 4A and 4B show diagrams of how this high voltage charging system can be used to generate plasma pulses in a single (FIG. 4A) or double (FIG. 4B) spark gap configuration. The single spark gap operates like so: the power supply is charging the storage capacitor until the voltage across the spark gap becomes sufficient for the breakdown and formation of a conductive channel. At the moment of formation of this conductive channel, the capacitor begins discharging and the power supply charging stops (as mentioned above and shown in FIG. 2). The thus-generated short and high voltage pulse is applied to the load (FIG. 4A) which can be a pulsed corona needle or a needle array, electrode of the dielectric barrier discharge, or another setup requiring short high voltage pulses for its operation.

The double spark gap, shown in FIG. 4B, operates on a similar principle as the single spark gap with the main difference being that the first spark gap (Spark gap 1) defines the break down voltage and the second spark gap (Spark gap 2) defines the length of the pulse. While the storage capacitor is being charged, voltage raises on the first spark gap (Spark gap 1), until a breakdown occurs. At that point, the voltage is applied to the Load and to the second spark gap (Spark gap 2). Discharging of the second spark gap (Spark gap 2) limits the duration of the pulse. Ultra-short high voltage pulses with the voltage raise and fall rates over 3 kV/ns are possible.

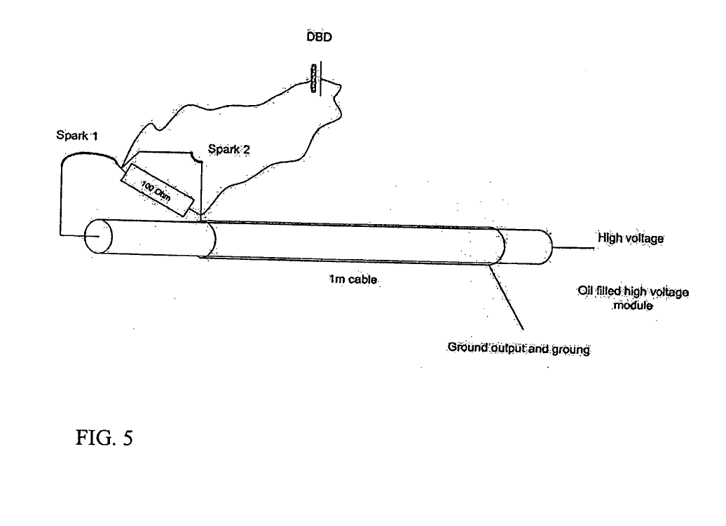

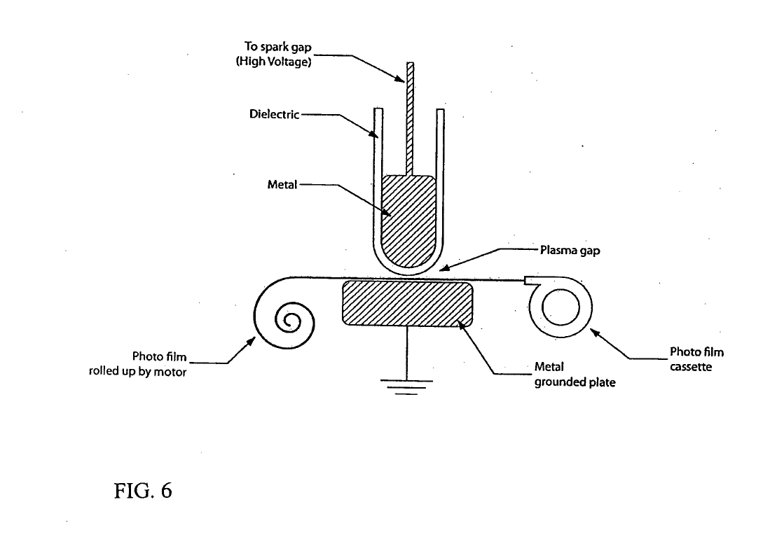

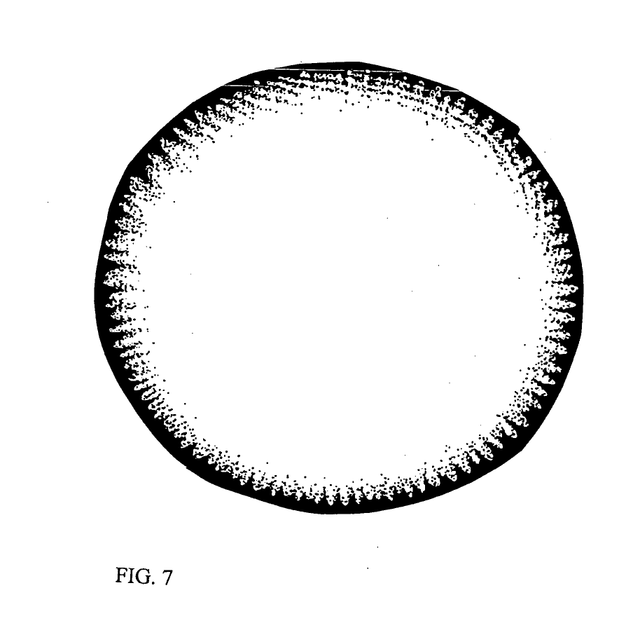

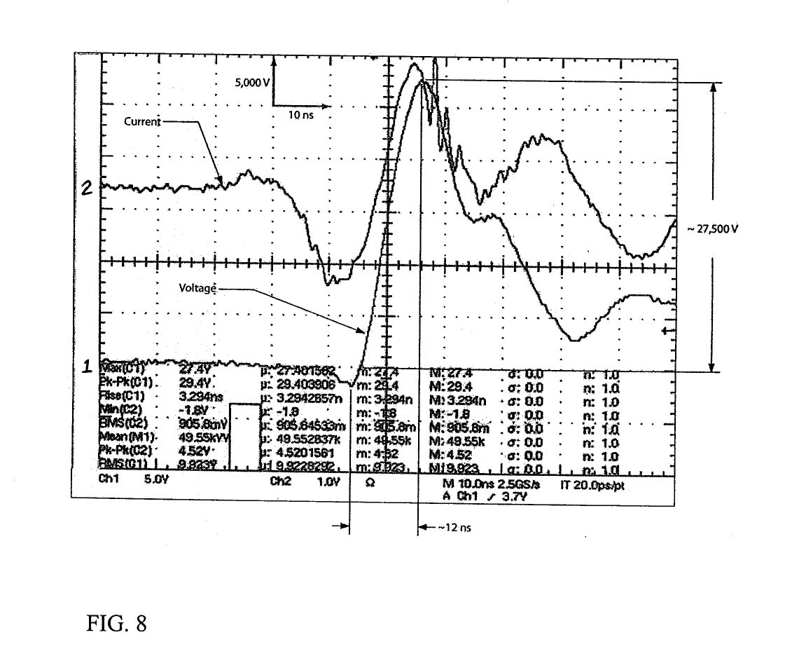

FIG. 5 shows a diagram of a construction of a Dielectric Barrier Discharge (DBD) system based on a double spark gap setup. This system is capable of pulsing high voltage with the voltage raise rates over 3 kV/ns and pulse width of below 20 ns. FIGS. 6 to 8 show such a discharge in operation. FIG. 6 shows a setup where high voltage ultra-short pulses are applied to an insulated electrode. This generated plasma discharge is applied to a rolling photo film, and in this way a single pulse of plasma is captured on film. FIG. 7 shows a result of such a pulse—a completely uniform plasma field. FIG. 8 shows a screen capture from a digital oscilloscope showing the voltage and current profiles of a single pulse of the nanosecond duration Dielectric Barrier Discharge (DBD) for the setup shown in FIG. 6 with the resulting image on the film shown in FIG. 7. Thus, this setup is able to generate a completely uniform and filament-free plasma at atmospheric pressure and temperature in open air, which can potentially be important for many applications where plasma discharge uniformity is of concern, for example is sterilization of living human tissue or other applications (see Fridman, et al, 2006).

From the foregoing disclosure and detailed description of certain preferred embodiments, it will be apparent that various modifications, additions and other alternative embodiments are possible without departing from the true scope and spirit of the present invention. The embodiments discussed were chosen and described to provide the best illustration of the principles of the present invention and its practical application to thereby enable one of ordinary skill in the art to utilize the invention in various embodiments and with various modifications as are suited to the particular use contemplated. All such modifications and variations are within the scope of the present invention as determined by the appended claims when interpreted in accordance with the benefit to which they are fairly, legally, and equitably entitled.

What is claimed is:

1. A pulsed power generator comprising, in combination:
a storage capacitor,
a high voltage switch operably connected to said storage capacitor, and
a charger of said storage capacitor which generates charging pulses until a spark gap breakdown occurs which gives a feedback signal to stop further charging until the beginning of the next charging cycle.

2. The pulsed power generator according to claim 1, further comprising a load operably connected to the storage capacitor with one or two spark gaps.

3. The pulsed power generator according to claim 1, further comprising a load operably connected to the storage capacitor with two spark gaps and a resistor for pulsed DBD operation.

4. The pulsed power generator according to claim 1, further comprising a load operably connected to the storage capacitor with two spark gaps and an inductor for pulsed DBD operation.

5. The pulsed power generator according to claim 1, wherein said pulsed DBD generates spatially uniform plasma.

6. The pulsed power generator according to claim 1, further comprising a load operably connected to the storage capacitor with two spark gaps and a resistor for a generation of fast ionization wave discharge.

7. The pulsed power generator according to claim 1, wherein said ionization wave is spatially uniform.

8. The pulsed power generator according to claim 1, further comprising a load operably connected to the storage capacitor with two spark gaps and a resistor for surface sterilization by non-thermal plasma.

9. The pulsed power generator according to claim 1, wherein said non-thermal plasma is spatially uniform.

10. The pulsed power generator according to claim 1, further comprising a load operably connected to the storage capacitor with one spark gap or two spark gaps for generation of corona discharge in water.

11. The pulsed power generator according to claim 1, further comprising a load operably connected to the storage capacitor with one spark gap or two spark gaps and a resistor for generation of spark discharge in water.

12. The pulsed power generator according to claim 1, further comprising a load operably connected to the storage capacitor with two spark gaps and an inductor for generation of spark discharge in water.

13. The pulsed power generator according to claim 1, wherein the generator is adapted for formation of non-thermal plasma in a corona discharge.

14. The pulsed power generator according to claim 1, wherein the generator is adapted for formation of non-thermal plasma in Dielectric Barrier Discharge.

15. The pulsed power generator according to claim 1, wherein the generator is adapted for formation of ultra-short pulsed non-thermal plasma between two open metal electrodes.

16. The pulsed power generator according to claim 1, wherein the generator is adapted for formation of microscopic (˜100 micron) plasma discharges.

17. The pulsed power generator according to claim 1, wherein the generator is adapted for treatment of surfaces and materials for surface modification, sterilization, disinfection, polymerization, and other purposes.

18. The pulsed power generator according to claim 1, wherein the generator is adapted for any type of treatment by non-thermal plasma at atmospheric pressure or at elevated or reduced pressure.

19. The pulsed power generator according to claim 1, wherein the generator is adapted for treatment by non-thermal plasma in open air at in various gasses or gas combinations.
